(19) United States
(12) Patent Application Publication
(10) Pub. No.: US 2026/0205125 A1
(43) Pub. Date: Jul. 16, 2026

(54) VOLTAGE-CONTROLLED OSCILLATION CIRCUIT

(71) Applicant: ROHM CO., LTD., Kyoto (JP)

(72) Inventor: Takashi TOMITA, Kyoto (JP)

(73) Assignee: ROHM CO., LTD., Kyoto (JP)

(21) Appl. No.: 19/448,276

(22) Filed: Jan. 14, 2026

(30) Foreign Application Priority Data
Jan. 16, 2025 (JP) 2025-006152

(51) Int. Cl. H03L 7/099; H03L 7/085

(52) U.S. Cl. CPC H03L 7/0992; H03L 7/085

(57) ABSTRACT

A voltage control circuit includes a voltage-controlled oscillator including an odd number of inverter elements connected in a loop. Each inverter element operates by an operating current corresponding to a control voltage. The voltage-controlled oscillator outputs an output from one of the odd number of inverter elements as the oscillation signal. The voltage control circuit further includes a threshold detection circuit including a first transistor in a diode connection, and a first resistor having a first end connected to a drain of the first transistor and a second end that has applied thereto a prescribed voltage. The threshold detection circuit detects a voltage of the drain of the first transistor as a threshold voltage of the first transistor. The voltage-controlled oscillator includes an operating current adjustment circuit that adjusts the operating current up or down if the threshold voltage is outside of a prescribed allowable voltage range.

### TECHNICAL FIELD

The present disclosure relates to a voltage-controlled oscillation circuit.

### BACKGROUND ART

In digital circuits, a phase locked loop (PLL) circuit including a voltage-controlled oscillator (VCO) that generates a clock signal at a frequency corresponding to a control voltage is used in order to attain a clock signal of a desired frequency.

The PLL circuit supplies, as a control voltage to the VCO, a voltage corresponding to the phase difference between a frequency-divided clock signal in which the frequency of the clock signal has undergone frequency division and a reference clock signal, thereby generating a clock signal of a desired frequency that is synchronized in phase with the reference clock signal.

Also, as such a PLL circuit, an oscillation circuit that repeatedly charges and discharges a capacitor in synchronization with each period of the frequency-divided clock signal and determines the difference between the voltage of the capacitor and the reference voltage as the phase difference is proposed (e.g., see Japanese Patent Application Laid-Open Publication No. 2020-167527, FIG. 8). This oscillation circuit is equipped with a circuit 190 that performs calibration in order to suppress frequency error resulting from manufacturing variation or temperature fluctuation. The circuit 190 includes a frequency detector that compares the frequency of the frequency-divided clock signal to the frequency of the reference clock signal, and repeatedly executes calibration by which the capacitance of the capacitor is adjusted up or down according to the comparison result until frequency-divided clock signal matches the reference clock signal.

### SUMMARY

Thus, in the oscillation circuit disclosed in Japanese Patent Application Laid-Open Publication No. 2020-167527, the circuit size is increased due to the need for a frequency detector and a variable capacitor in order to perform calibration. There has also been the problem that during testing for when the product is shipped, a relatively long period of time is required for calibration testing, which increases the testing cost.

A voltage-controlled oscillation circuit according to the present disclosure is a voltage-controlled oscillation circuit that receives a control voltage and generates an oscillation signal of a frequency corresponding to a value of the control voltage, the voltage-controlled oscillation circuit including: a voltage-controlled oscillator including an odd number of inverter elements connected in a loop, each of which operates by an operating current corresponding to a value of the control voltage, the voltage-controlled oscillator outputting an output from one of the odd number of inverter elements as the oscillation signal; and a detection circuit including a first transistor in a diode connection, and a first resistor having a first end that is connected to a drain of the first transistor and a second end that has applied thereto a prescribed voltage, the threshold detection circuit detecting a voltage of the drain of the first transistor as a threshold voltage of the first transistor, wherein the voltage-controlled oscillator includes an adjustment circuit that adjusts the operating current up or down if the threshold voltage is outside of a prescribed voltage range.

### BRIEF DESCRIPTION OF THE DRAWINGS

FIG. 1 is a block diagram showing a configuration of a PLL circuit 100 including a voltage-controlled oscillation circuit of the present embodiment.

FIG. 2 is a circuit diagram showing an internal configuration of a threshold detection/determination circuit 140.

FIG. 3 is a circuit diagram showing an internal configuration of a VCO 141.

FIG. 4 is a circuit diagram showing an internal configuration of inversion delay cells CE1 to CE3.

FIG. 5 shows control voltage/frequency characteristics of the VCO 141 indicating the relationship between a control voltage Vctrl and a frequency of an output clock signal CLK.

FIG. 6 shows an operation aspect of the threshold detection/determination circuit 140 and an operating current adjustment circuit CAC.

### DETAILED DESCRIPTION OF EMBODIMENTS

### Embodiment 1

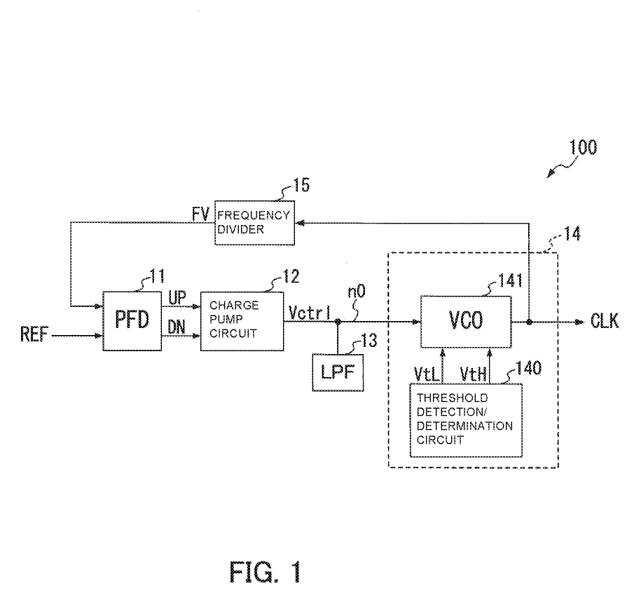

FIG. 1 is a block diagram showing a configuration of a PLL circuit 100 including a voltage-controlled oscillation circuit of the present embodiment.

The PLL circuit 100 receives a reference clock signal REF, generates a binary oscillation signal of a prescribed frequency that is synchronized in phase to the reference clock signal REF, and outputs the oscillation signal as an output clock signal CLK.

As shown in FIG. 1, the PLL circuit 100 is constituted of a phase comparator 11 (PFD), a charge pump circuit 12, a loop filter 13 (LPF), a voltage-controlled oscillation circuit 14 of the present disclosure, and a frequency divider 15.

The phase comparator 11 detects the difference between the rising edges of the reference clock signal REF and a frequency-divided oscillation signal FV supplied from the frequency divider 15.

Here, if the detected phase difference indicates a lagging phase in which the rising edge of the frequency-divided oscillation signal FV is delayed compared to the rising edge of the reference clock signal REF, then the phase comparator 11 generates a phase difference signal UP with a pulse width corresponding to the phase difference. On the other hand, if the detected phase difference indicates a leading phase in which the rising edge of the frequency-divided oscillation signal FV is earlier compared to the rising edge of the reference clock signal REF, then the phase comparator 11 generates a phase difference signal DN with a pulse width corresponding to the phase difference.

The phase comparator 11 supplies the generated phase difference signals UP and DN to the charge pump circuit 12.

Upon receiving the phase difference signal UP, the charge pump circuit 12 generates a charge pump current having a prescribed value, and supplies the charge pump current to a node n0. As a result, the voltage of the node n0 increases. On the other hand, upon receiving the phase difference signal DN, the charge pump circuit 12 subtracts the charge pump current from the node n0. As a result, the voltage of the node n0 decreases.

By the operation of the charge pump circuit 12, a control voltage Vctrl having a value corresponding to the phase difference between the reference clock signal REF and the frequency-divided oscillation signal FV is generated at the node n0.

The loop filter 13 smooths the voltage of the node n0, or in other words, the control voltage Vctrl. As a result, the control voltage Vctrl, which was smoothed by the loop filter 13, is supplied to the voltage-controlled oscillation circuit 14.

The voltage-controlled oscillation circuit 14 receives the control voltage Vctrl via the node n0, generates an oscillation signal having a frequency corresponding to the value of the control voltage Vctrl as the output clock signal CLK, and outputs the output clock signal CLK.

The frequency divider 15 receives the output clock signal CLK outputted from the voltage-controlled oscillation circuit 14, and supplies, to the phase comparator 11, the frequency division signal FV resulting from performing frequency division on the output clock signal CLK according to a prescribed frequency division ratio or a designated frequency division ratio.

Next, the configuration of the voltage-controlled oscillation circuit 14 will be explained in detail.

As shown in FIG. 1, the voltage-controlled oscillation circuit 14 includes a threshold detection/determination circuit 140 and a voltage-controlled oscillator 141 (VCO). The threshold detection/determination circuit 140 and the VCO 141 are formed on the same semiconductor substrate.

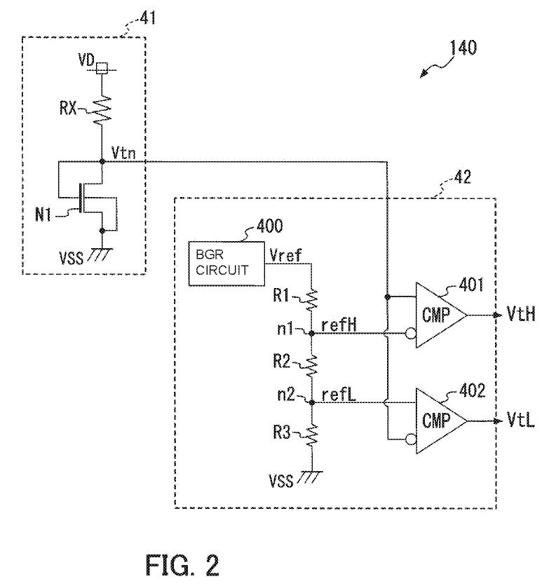

FIG. 2 is a circuit diagram showing an internal configuration of a threshold detection/determination circuit 140. As shown in FIG. 2, the threshold detection/determination circuit 140 includes a threshold detection circuit 41 and a threshold determination circuit 42.

The threshold detection circuit 41 includes a resistor RX and an N-channel-type transistor N1.

The resistor RX has a high resistance of 100 kiloohms or greater, for example, and a power source voltage VD is applied to a first end thereof and a second end thereof is connected to the drain of the transistor N1.

The transistor N1 is a so-called diode-connected transistor in which the drain and gate thereof are connected to each other, and a ground voltage VSS is applied to the source thereof. The transistor N1 is a metal oxide semiconductor (MOS) transistor having the same structure and characteristics as a transistor constituting an oscillation circuit in the VCO 141 (to be described later).

By this configuration, a voltage occurring at the drain of the transistor N1 is detected as a threshold voltage Vtn of the transistor N1, and the threshold voltage Vtn is supplied to the threshold determination circuit 42.

The threshold voltage Vtn of the transistor N1 fluctuates due to manufacturing variation or temperature fluctuation.

The threshold determination circuit 42 has resistors R1 to R3, a bandgap reference (BGR) circuit 400, and comparators 401 and 402.

The BGR circuit 400 generates a reference voltage Vref of 1.25 volts (or a current), for example, that is not dependent on the power source voltage, the temperature, or the manufacturing process, and applies the reference voltage Vref to a first end of the resistor R1.

The resistors R1 to R3 are connected in series, and the ground voltage VSS is applied to a first end of the resistor R3. The resistors R1 to R3 perform voltage division on the reference voltage Vref at respective resistance ratios. As a result, the resistors R1 to R3 supply the voltage occurring at a connection node n1 between the resistors R1 and R2 to the comparator 401 as an upper limit voltage refH representing the upper limit of an allowable voltage range (hereinafter referred to as an allowable voltage range) of the threshold voltage Vtn according to the specifications. Additionally, the resistors R1 to R3 supply the voltage occurring at a connection node n2 between the resistors R2 and R3 to the comparator 401 as a lower limit voltage refL representing the lower limit of the allowable voltage range.

The comparator 401 receives the threshold voltage Vtn and the upper limit voltage refH, and generates a detection signal VtH with a logic level of 1 if the threshold voltage Vtn is higher than the upper limit voltage refH and a logic level of 0 if the threshold voltage Vtn is less than or equal to the upper limit voltage refH. The comparator 401 then supplies the detection signal VtH to the VCO 141.

The comparator 402 receives the threshold voltage Vtn and the lower limit voltage refL, and generates a detection signal VtL with a logic level of 1 if the threshold voltage Vtn is lower than the lower limit voltage refL and a logic level of 0 if the threshold voltage Vtn is greater than or equal to the lower limit voltage refL. The comparator 402 then supplies the detection signal VtL to the VCO 141.

Thus, according to this configuration, the threshold determination circuit 42 determines whether the threshold voltage Vtn detected by the threshold detection circuit 41 is within the allowable voltage range (refL to refH), and outputs the determination result as the detection signals VtL and VtH. That is, if the threshold voltage Vtn is within the allowable voltage range, the detection signals VtL and VtH supplied to the threshold determination circuit 42 both have a logic level of 0.

On the other hand, if the threshold voltage Vtn is outside of the allowable voltage range, and in particular, if the threshold voltage Vtn is higher than the upper limit voltage refH, then the threshold determination circuit 42 supplies, to the VCO 141, a detection signal VtL with a logic level of 0 and a detection signal VtH with a logic level of 1, which together indicate the aforementioned state. If the threshold voltage Vtn is lower than the lower limit voltage refL, then the threshold determination circuit 42 supplies, to the VCO 141, a detection signal VtL with a logic level of 1 and a detection signal VtH with a logic level of 0, which together indicate the aforementioned state.

The VCO 141 generates an oscillation signal having a frequency corresponding to the value of the control voltage Vctrl as the output clock signal CLK. Additionally, the VCO 141 has an adjustment function that adjusts the frequency of the output clock signal CLK on the basis of the detection signal VtH and the detection signal VtL supplied from the threshold voltage detection circuit 140.

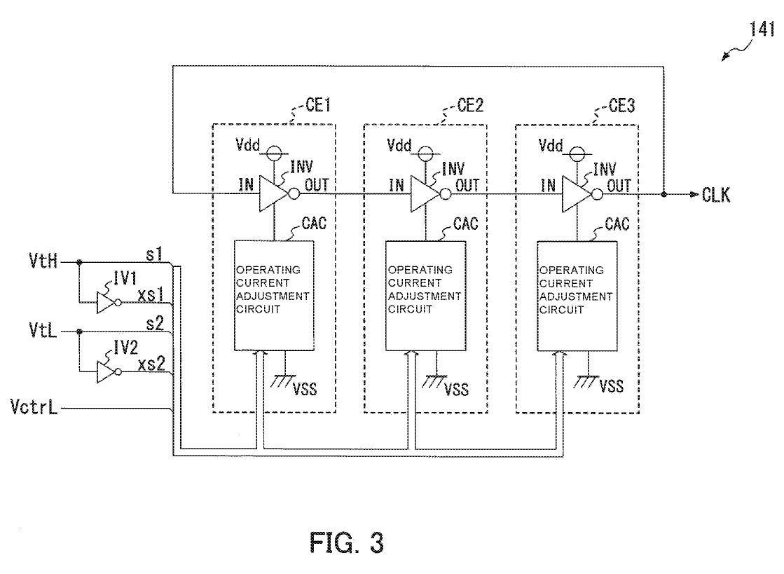

FIG. 3 is a circuit diagram showing the internal configuration of the VCO 141. As shown in FIG. 3, the VCO 141 includes inverter elements IV1 and IV2 and inversion delay cells CE1 to CE3.

The inversion delay cells CE1 to CE3 have the same internal configuration; that is, each inversion delay cell includes an inverter element INV and an operating current adjustment circuit CAC.

The inverter elements INV included in the respective inversion delay cells CE1 to CE3 are, as shown in FIG. 3, connected in a loop such that the output terminal of each inverter element is connected to the input terminal of another inverter element INV. In this case, the oscillation signal with a frequency of 1/(output delay time of 6×inverter elements INV) outputted from the inverter element INV of the inversion delay cell CE3 is the output clock signal CLK. That is, in the VCO 141, the oscillation circuit is constituted of the three inverter elements INV connected in a loop.

The operating current adjustment circuits CAC included in the respective inversion delay cells CE1 to CE3 receive the control voltage Vctrl.

Also, each operating current adjustment circuit CAC receives the binary (logic level of 0 or 1) detection signal VtH supplied from the threshold detection/determination circuit 140 as the switching signal s1 and receives the binary (logic level of 0 or 1) detection signal VtL as the switching signal s2. Additionally, each operating current adjustment circuit CAC receives a switching signal xs1 in which the logic level is inverted from the switching signal s1 by the inverter element IV1 and a switching signal xs2 in which the logic level is inverted from the switching signal s2 by the inverter element IV2.

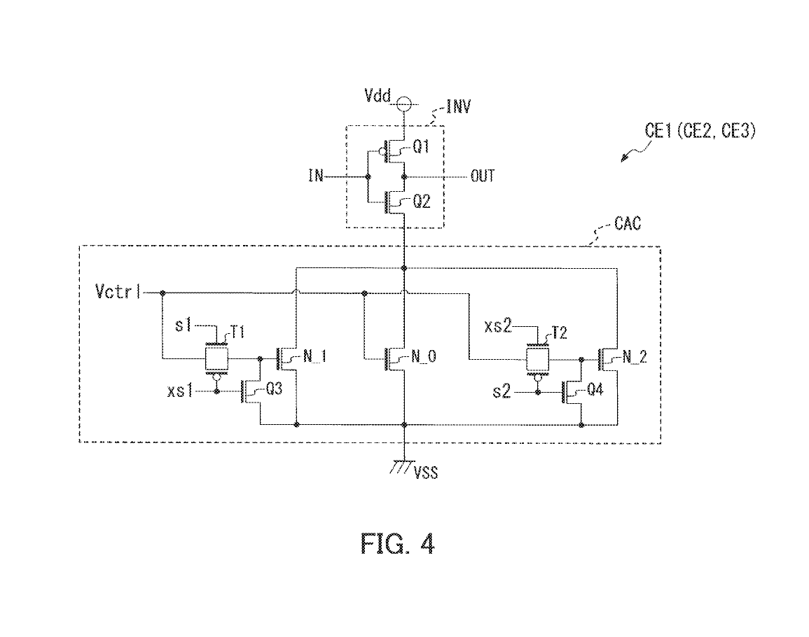

FIG. 4 is a circuit diagram showing the internal configuration of the inversion delay cells CE1 to CE3.

As shown in FIG. 4, the inverter element INV of each inversion delay cell CE1 to CE3 includes a P-channel-type transistor Q1 and an N-channel-type transistor Q2. The gates of the transistors Q1 and Q2 are both connected to an input terminal IN and the drains of the transistors Q1 and Q2 are both connected to an output terminal OUT. The transistor Q1 receives, at the source thereof, the power source voltage Vdd for the logic circuit. The source of the transistor Q2 is connected to the operating current adjustment circuit CAC.

The operating current adjustment circuit CAC includes N-channel-type transistors N_0, N_1, N_2, Q3, and Q4, and transmission gates T1 and T2.

The N-channel-type transistors N_0, N_1, and N-2 are formed on the semiconductor substrate on which the transistor N1 included in the threshold detection/determination circuit 140 is formed, and are MOS transistors having the same structure and characteristics as the transistor N1.

The transistors N_0, N_1, and N_2 are current sources that generate operating currents that flow to the inverter element INV. The drains of the transistors N_0, N_1, and N_2 are connected to the same source of the transistor Q2 of the inverter element INV, and the sources of the transistors N_0, N_1, and N_2 receive the ground voltage VSS.

The gate of the transistor N_0 receives the control voltage Vctrl, and the transistor N_0 passes a current corresponding in value to the control voltage Vctrl to the transistors Q1 and Q2 of the inverter element INV as the operating current.

The transmission gate T1 receives the switching signal s1 (VtH) at the positive-side terminal thereof, and receives the switching signal xs1 at the negative-side terminal thereof. Additionally, the transmission gate T1 receives the control voltage Vctrl and turns ON when the switching signal s1 has a logic level of 1, and supplies the control voltage Vctrl to the gate of the transistor N_1. On the other hand, if the switching signal s1 has a logic level of 0, the transmission gate T1 turns OFF.

The drain of the transistor Q3 is connected to the gate of the transistor N_1 and the source of the transistor Q3 receives the ground voltage VSS. The gate of the transistor Q3 receives the switching signal xs1, and if the switching signal xs1 has a logic level of 1, the transistor Q3 turns ON and applies the ground voltage VSS to the gate of the transistor N_1. On the other hand, if the switching signal xs1 has a logic level of 0, the transistor Q3 turns OFF.

That is, if the switching signal s1, or in other words, the detection signal VtH has a logic level of 1, the transmission gate T1 and the transistor Q3 supply the control voltage Vctrl to the gate of the transistor N_1. On the other hand, if the switching signal s1 (VtH) has a logic level of 0, then the ground voltage VSS is supplied to the gate of the transistor N_1.

The transistor N_1 turns ON upon receiving, at the gate thereof, the control voltage Vctrl, and adds a current corresponding in value to the control voltage Vctrl to the operating current passed by the transistor N_0 to the transistors Q1 and Q2 of the inverter element INV. On the other hand, if the gate thereof receives the ground voltage VSS, the transistor N_1 turns OFF.

The transmission gate T2 receives the switching signal xs2 at the positive-side terminal thereof, and receives the switching signal s2 (VtL) at the negative-side terminal thereof. Additionally, the transmission gate T2receives the control voltage Vctrl and turns ON when the switching signal s2 has a logic level of 0, and supplies the control voltage Vctrl to the gate of the transistor N_2. On the other hand, if the switching signal s2 has a logic level of 1, the transmission gate T2 turns OFF.

The drain of the transistor Q4 is connected to the gate of the transistor N_2 and the source of the transistor Q4 receives the ground voltage VSS. The gate of the transistor Q4 receives the switching signal s2, and if the switching signal s2 has a logic level of 1, the transistor Q4 turns ON and applies the ground voltage VSS to the gate of the transistor N_2. On the other hand, if the switching signal s2 has a logic level of 0, the transistor Q4 turns OFF.

That is, if the switching signal s2, or in other words, the detection signal VtL has a logic level of 0, the transmission gate T2 and the transistor Q4 supply the control voltage Vctrl to the gate of the transistor N_2. On the other hand, if the switching signal s2 (VtL) has a logic level of 1, then the ground voltage VSS is supplied to the gate of the transistor N_2.

The transistor N_2 turns ON upon receiving, at the gate thereof, the control voltage Vctrl, and adds a current corresponding in value to the control voltage Vctrl to the operating current passed by the transistor N_0 to the transistors Q1 and Q2 of the inverter element INV. On the other hand, if the gate thereof receives the ground voltage VSS, the transistor N_2 turns OFF.

Below, the operation of the threshold detection/determination circuit 140 and the VCO 141 will be described in detail.

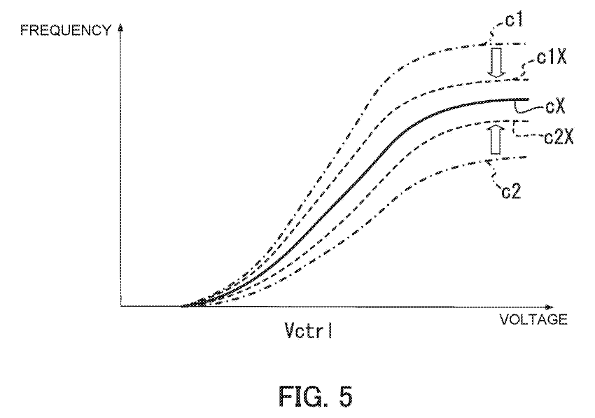

FIG. 5 shows control voltage/frequency characteristics of the VCO 141 indicating the relationship between the control voltage Vctrl and the frequency of the output clock signal CLK.

FIG. 5 shows standard control voltage/frequency characteristics cX (bold solid line), and control voltage/frequency characteristics c1 or c2 (dashed-dotted lines) for when manufacturing variation, temperature fluctuation, or the like occurs.

As shown in FIG. 5, the frequency of the output clock signal CLK outputted by the VCO 141 according to the control voltage Vctrl increases (c1) or decreases (c2) compared to the frequency indicated by the standard control voltage/frequency characteristics cX due to the effect of manufacturing variation or the ambient temperature.

Here, a cause for fluctuation in the frequency of the output clock signal CLK is the fluctuation in output delay time of the inverter element INV resulting from manufacturing variation and fluctuation in the ambient temperature. In other words, the longer the output delay time of each inverter element INV is, the lower the frequency of the output clock signal CLK is.

The output delay time of the inverter element INV is determined by the operating current of the inverter element INV. Furthermore, the operating current of the inverter element INV is determined by the threshold voltages of the transistors N_0, N_1, and N_2. If, for example, manufacturing variation or fluctuation in the ambient temperature results in the threshold voltages of the transistors N_0, N_1, and N_2 to be higher than the standard value, then the operating current of the inverter element INV is reduced, which lengthens the output delay time. If the threshold voltages are lower than the standard value, then the operating current of the inverter element INV is increased, which shortens the output delay time.

The voltage-controlled oscillation circuit 14 of the present disclosure is provided with the threshold detection/determination circuit 140, which detects the threshold voltage Vtn of the transistor N1 having the same structure and characteristics as the transistors N_0, N_1, and N_2. Additionally, the voltage-controlled oscillation circuit 14 adopts a configuration in which the operating current adjustment circuits CAC, which individually adjust the operating current of each inverter element INV on the basis of the detected threshold voltage Vtn, are installed on the VCO 141.

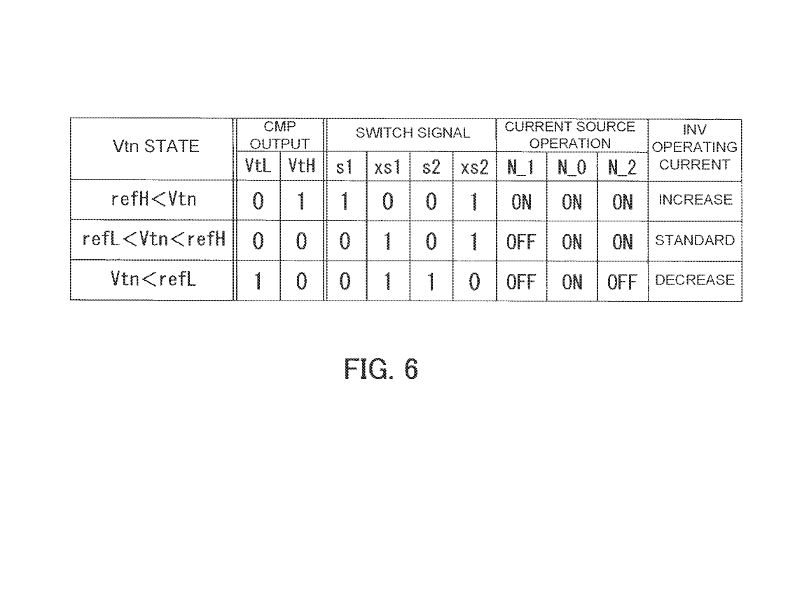

FIG. 6 shows an operation aspect of the threshold detection/determination circuit 140 and the operating current adjustment circuit CAC.

First, if the threshold voltage Vtn of the transistor N1 detected by the threshold detection/determination circuit 140 is higher than the upper limit voltage refH, then as shown in FIG. 6, the comparators 401 and 402 output the detection signals VtH and VtL with logic levels of [1, 0]. If the threshold voltage Vtn is higher than the upper limit voltage refH, the frequency of the output clock signal CLK outputted by the VCO 141 according to the control voltage Vctrl is lower than the allowable lower limit frequency. Thus, in this case, the control voltage/frequency characteristics of the VCO 141 are, as shown in FIG. 5, for example, the control voltage/frequency characteristics c2 in which the frequency of the output clock signal CLK in relation to the control voltage Vctrl is lower than that of the standard control voltage/frequency characteristics cX. In this case (refH<Vtn), in the operating current adjustment circuit CAC, the transistors N_0 to N_2 of the current source all turn ON according to the switching signals s1, xs1, s2, and xs2 having logic levels of [1, 0, 0, 1]. Thus, the operating current adjustment circuit CAC passes a current resulting from combining the currents flowing through the transistors N_0 to N_2 as a maximum operating current to the inverter element INV. As a result, the frequency of the output clock signal CLK outputted by the VCO 141 according to the control voltage Vctrl increases. Thus, in this case, the control voltage/frequency characteristics of the VCO 141, as indicated by the hollow arrow of FIG. 5, for example, transition from the control voltage/frequency characteristics c2 to the control voltage/frequency characteristics c2X. Therefore, the control voltage/frequency characteristics of the VCO 141 approach the standard control voltage/frequency characteristics cX, and thus, the error of the frequency of the output clock signal CLK generated on the basis of the control voltage Vctrl is reduced.

Also, if the threshold voltage Vtn detected by the threshold detection/determination circuit 140 is within the allowable voltage range (refL to refH), then as shown in FIG. 6, the comparators 401 and 402 output the detection signals VtH and VtL indicating logic levels of [0, 0]. If the threshold voltage Vtn is within the allowable voltage range, the frequency of the output clock signal CLK outputted by the VCO 141 according to the control voltage Vctrl also falls within a desirable frequency range. In this case (refL<Vtn<refH), in the operating current adjustment circuit CAC, the transistors N_0 and N_2 turn ON and the transistor N_1 turns OFF according to the switching signals S1, xs1, s2, and xs2 having logic levels of [0, 1, 0, 1]. Thus, the operating current adjustment circuit CAC passes a current that is one level lower than the maximum operating current resulting from combining the currents flowing through the transistors N_0 and N_2 as an intermediate operating current to the inverter element INV. As a result, the frequency of the output clock signal CLK outputted by the VCO 141 according to the control voltage Vctrl follows the standard control voltage/frequency characteristics cX or characteristics similar thereto.

Also, if the threshold voltage Vtn detected by the threshold detection/determination circuit 140 is lower than the lower limit voltage refL, then as shown in FIG. 6, the comparators 401 and 402 output the detection signals VtH and VtL with logic levels of [0, 1]. If the threshold voltage Vtn is lower than the lower limit voltage refL, the frequency of the output clock signal CLK outputted by the VCO 141 according to the control voltage Vctrl is higher than the allowable upper limit frequency. Thus, in this case, the control voltage/frequency characteristics of the VCO 141 are, as shown in FIG. 5, for example, the control voltage/frequency characteristics c1 in which the frequency of the output clock signal CLK in relation to the control voltage Vctrl is higher than that of the standard control voltage/frequency characteristics cX. In this case (Vtn<refL), in the operating current adjustment circuit CAC, the transistors N_1 and N_2 turn OFF and the transistor N_0 turns ON according to the switching signals s1, xs1, s2, and xs2 having logic levels of [0, 1, 1, 0]. Thus, the operating current adjustment circuit CAC passes the current passed by the transistor N_0, or in other words, a current that is one level lower than the intermediate operating current as an operating current to the inverter element INV. As a result, the frequency of the output clock signal CLK outputted by the VCO 141 according to the control voltage Vctrl decreases. Thus, in this case, the control voltage/frequency characteristics of the VCO 141, as indicated by the hollow arrow of FIG. 5, for example, transition from the control voltage/frequency characteristics c1 to the control voltage/frequency characteristics c1X. Therefore, the control voltage/frequency characteristics of the VCO 141 approach the standard control voltage/frequency characteristics cX, and thus, the error of the frequency of the output clock signal CLK generated on the basis of the control voltage Vctrl is reduced.

In this manner, in the operating current adjustment circuit CAC, only one (N_0) of the three transistors N_0 to N_2 is turned ON, only two (N_0, N_2) of the transistors are turned ON, or all three transistors are turned ON, on the basis of the detection signals VtH and VtL. As a result, the operating current flowing to the inverter element INV is adjusted to one of three levels, and by this adjustment, the frequency of the output clock signal CLK is changed.

Thus, as a result of the adjustment of the operating current described above, it is possible to reduce any error in frequency of the output clock signal CLK that occurs as a result of manufacturing variation, temperature fluctuation, or the like.

Here, in the voltage-controlled oscillation circuit 14 of the present disclosure, the following circuit configuration is adopted as the configuration for adjusting the error in frequency of the output clock signal CLK occurring as a result of manufacturing variation, temperature fluctuation, or the like. In the voltage-controlled oscillation circuit 14, first, the threshold voltage Vtn of the transistor N1 that fluctuates due to manufacturing variation, temperature fluctuation, or the like is detected. In the voltage-controlled oscillation circuit 14, if the threshold voltage Vtn is outside of the prescribed allowable voltage range (refL to refH), then the operating current flowing to each of the inverter elements INV constituting the oscillation circuit is increased or decreased to adjust the frequency of the output clock signal CLK.

Thus, according to the voltage-controlled oscillation circuit 14, it is possible to reduce the circuit size compared to the configuration of Japanese Patent Application Laid-Open Publication No. 2020-167527 in which a frequency detector is used to compare the frequencies of a frequency-divided clock signal and a reference clock signal, and the capacitance of a variable capacitor is controlled according to the comparison result.

Additionally, according to the voltage-controlled oscillation circuit 14 of the present disclosure, it is possible to reduce the testing time for when the product is shipped compared to the configuration of Japanese Patent Application Laid-Open Publication No. 2020-167527 in which calibration through repeated change of the capacitance of the variable capacitor is performed until the frequencies of the frequency-divided clock signal and the reference clock signal match each other.

In the VCO 141 indicated in the embodiment, as shown in FIG. 3, the oscillation circuit is constituted of three inverter elements INV connected in a loop, but the number of inverter elements INV connected in a loop is not limited to three. That is, any configuration may be adopted as long as the VCO 141 includes an oscillation circuit in which an odd number of inverter elements INV are connected in a loop, and operating current adjustment circuits CAC that adjust the operating currents flowing to the respective inverter elements INV.

Also, in the voltage-controlled oscillation circuit 14 shown in FIG. 1, the threshold determination circuit 42 shown in FIG. 2 is provided in the threshold detection/determination circuit 140 outside of the VCO 141, but the threshold determination circuit 42 may alternatively be provided in the VCO 141.

Essentially, any configuration may be adopted as long as the voltage-controlled oscillation circuit of the present disclosure, which generates an oscillation signal (CLK) of a frequency corresponding to the value of a control voltage (Vctrl), includes the following VCO and threshold detection circuit.

That is, the VCO (141) includes an odd number of inverter elements (INV) connected in a loop, each of which operates by an operating current corresponding to the value of the control voltage (Vctrl), and outputs the output from one of the odd number of inverter elements as the oscillation signal (CLK). The threshold detection circuit (41) includes a first transistor (N1) in a diode connection, and a first resistor (RX) having a first end that is connected to the drain of the first transistor and a second end that has applied thereto a prescribed voltage, and the voltage of the drain of the first transistor is detected as the threshold voltage of the first transistor. The VCO (141) includes an operating current adjustment circuit (CAC) that adjusts the operating current up or down if the detected threshold voltage is outside of the prescribed allowable voltage range (refL to refH).

The present disclosure is not limited to the above-mentioned aspects of the embodiment, and various revisions and design modifications can be made within a scope that does not deviate from the gist of the present disclosure.

<Notes> The present specification discloses the following configurations.

### Configuration 1

A voltage-controlled oscillation circuit that receives a control voltage and generates an oscillation signal of a frequency corresponding to a value of the control voltage, the voltage-controlled oscillation circuit including: a voltage-controlled oscillator including an odd number of inverter elements connected in a loop, each of which operates by an operating current corresponding to a value of the control voltage, the voltage-controlled oscillator outputting an output from one of the odd number of inverter elements as the oscillation signal; and a threshold detection circuit including a first transistor in a diode connection, and a first resistor having a first end that is connected to a drain of the first transistor and a second end that has applied thereto a prescribed voltage, the threshold detection circuit detecting a voltage of the drain of the first transistor as a threshold voltage of the first transistor, wherein the voltage-controlled oscillator includes an operating current adjustment circuit that adjusts the operating current up or down if the threshold voltage is outside of a prescribed voltage range.

### Configuration 2

The voltage-controlled oscillation circuit according to configuration 1, wherein the first transistor has a same structure and characteristic as transistors constituting the respective odd number of inverter elements.

### Configuration 3

The voltage-controlled oscillation circuit according to configuration 1 or 2, wherein the operating current adjustment circuit adjusts the operating current up if the threshold voltage is higher than an upper limit value of the voltage range, and adjusts the operating current down if the threshold voltage is less than a lower limit value of the voltage range.

### Configuration 4

The voltage-controlled oscillation circuit according to configuration 3, further including: a first comparator that determines whether the threshold voltage is higher than the upper limit value of the voltage range, and generates a first detection signal indicating a determination result thereof; and a second comparator that determines whether the threshold voltage is lower than the lower limit value of the voltage range, and generates a second detection signal indicating a determination result thereof, wherein the operating current adjustment circuit receives the first detection signal and the second detection signal, performs an adjustment to increase the operating current on the basis of the first detection signal and an adjustment to decrease the operating current on the basis of the second detection signal.

### Configuration 5

The voltage-controlled oscillation circuit according to configuration 4, wherein each of the inverter elements includes: a first conductivity-type transistor that receives a power source voltage at a source thereof; and a second conductivity-type transistor having a drain that is connected to a drain of the first conductivity-type transistor, and a gate that is connected to a gate of the first conductivity-type transistor, and wherein the operating current adjustment circuit includes: first to third second conductivity-type transistors having drains connected to a source of the second conductivity-type transistor; and a switching circuit that turns ON all of the first to third second conductivity-type transistors if the first detection signal indicates that the threshold voltage is higher than the upper limit value of the voltage range, and turns ON only one of the first to third second conductivity-type transistors if the second detection signal indicates that the threshold voltage is lower than the lower limit value of the voltage range.

What is claimed is:

1. A voltage-controlled oscillation circuit that receives a control voltage and generates an oscillation signal of a frequency corresponding to a value of the control voltage, the voltage-controlled oscillation circuit comprising:
a voltage-controlled oscillator including an odd number of inverter elements connected in a loop, each of which operates by an operating current corresponding to a value of the control voltage, the voltage-controlled oscillator outputting an output from one of the odd number of inverter elements as the oscillation signal; and
a threshold detection circuit including a first transistor in a diode connection, and a first resistor having a first end that is connected to a drain of the first transistor and a second end that has applied thereto a prescribed voltage, the threshold detection circuit detecting a voltage of the drain of the first transistor as a threshold voltage of the first transistor,
wherein the voltage-controlled oscillator includes an operating current adjustment circuit that adjusts the operating current up or down if the threshold voltage is outside of a prescribed voltage range.

2. The voltage-controlled oscillation circuit according to claim 1,
wherein the first transistor is formed on a semiconductor substrate that has formed thereon a transistor that passes the operating current to each of the odd number of inverter elements, and has a same structure and characteristic as the transistor that passes the operating current to each of the odd number of inverter elements.

3. The voltage-controlled oscillation circuit according to claim 1,
wherein the operating current adjustment circuit adjusts the operating current up if the threshold voltage is higher than an upper limit value of the voltage range, and adjusts the operating current down if the threshold voltage is less than a lower limit value of the voltage range.

4. The voltage-controlled oscillation circuit according to claim 3, further comprising:
a first comparator that determines whether the threshold voltage is higher than the upper limit value of the voltage range, and generates a first detection signal indicating a determination result thereof; and
a second comparator that determines whether the threshold voltage is lower than the lower limit value of the voltage range, and generates a second detection signal indicating a determination result thereof,
wherein the operating current adjustment circuit receives the first detection signal and the second detection signal, performs an adjustment to increase the operating current on the basis of the first detection signal and an adjustment to decrease the operating current on the basis of the second detection signal.

5. The voltage-controlled oscillation circuit according to claim 4,
wherein each of the inverter elements includes:
a first conductivity-type transistor that receives a power source voltage at a source thereof; and
a second conductivity-type transistor having a drain that is connected to a drain of the first conductivity-type transistor, and a gate that is connected to a gate of the first conductivity-type transistor, and
wherein the operating current adjustment circuit includes:
first to third second conductivity-type transistors having drains connected to a source of the second conductivity-type transistor; and
a switching circuit that turns ON all of the first to third second conductivity-type transistors if the first detection signal indicates that the threshold voltage is higher than the upper limit value of the voltage range, and turns ON only one of the first to third second conductivity-type transistors if the second detection signal indicates that the threshold voltage is lower than the lower limit value of the voltage range.

6. The voltage-controlled oscillation circuit according to claim 1, wherein the threshold detection circuit further includes a bandgap reference (BGR) circuit configured to generate a reference voltage for comparison with the threshold voltage, for a determination of whether the threshold voltage is within the prescribed voltage range.

7. The voltage-controlled oscillation circuit according to claim 6, wherein the threshold detection circuit further comprises multiple series-connected resistors configured to divide the reference voltage to generate an upper limit voltage of the prescribed voltage range and a lower limit voltage of the prescribed voltage range.

8. The voltage-controlled oscillation circuit according to claim 6, wherein the operating current adjustment circuit is configured to, based on a result of the determination, adjust the operating current to one of an intermediate level, a level higher than the intermediate level, and a level lower than the intermediate level.

9. The voltage-controlled oscillation circuit according to claim 8, wherein the operating current adjustment circuit includes three logic elements configured to take on states based on the result of the determination, the states corresponding respectively to the intermediate level, the level higher than the intermediate level, and the level lower than the intermediate level.

10. The voltage-controlled oscillation circuit according to claim 7, wherein the operating current adjustment circuit includes three transistors configured to take on states of:
two ON and one OFF in response to the threshold voltage being between the upper limit voltage and the lower limit voltage, corresponding to an intermediate level of the operating current;
all ON in response to the threshold voltage being greater than the upper limit voltage, corresponding to a level of the operating current greater than the intermediate level;
two OFF and one ON in response to the threshold voltage being less than the lower limit voltage, corresponding to a level of the operating current less than the intermediate level.

11. A phase locked loop (PLL) circuit, comprising:
a frequency divider;
a voltage-controlled oscillation circuit coupled to the frequency divider and configured to output an oscillation signal to the frequency divider; and
a phase comparator coupled to the frequency divider, and configured to receive a reference clock signal and a frequency-divided oscillation signal output by the frequency divider, and to output a phase difference signal based on the reference clock signal and the frequency-divided oscillation signal;
wherein the voltage-controlled oscillation circuit is configured to receive a control voltage based on the phase difference signal and to generate the oscillation signal, the oscillation signal having a frequency corresponding to a value of the control voltage, the voltage-controlled oscillation circuit comprising:
a voltage-controlled oscillator including an odd number of inverter elements connected in a loop, each configured to operate by an operating current corresponding to a value of the control voltage, the voltage-controlled oscillator configured to supply an output from one of the odd number of inverter elements as the oscillation signal; and
a threshold detection circuit including a first transistor in a diode connection, and a first resistor having a first end that is connected to a drain of the first transistor and a second end that has applied thereto a prescribed voltage, the threshold detection circuit configured to detect a voltage of the drain of the first transistor as a threshold voltage of the first transistor,
wherein to adjust the frequency of the oscillation signal, the voltage-controlled oscillator includes an operating current adjustment circuit configured to adjust the operating current up or down in response to the threshold voltage being outside of an allowable voltage range.
